(19) United States
(12) Patent Application Publication
(10) Pub. No.: US 2021/0381100 A1
(43) Pub. Date: Dec. 9, 2021

(54) VACUUM TREATMENT APPARATUS AND METHOD OF VACUUM TREATING SUBSTRATES

(71) Applicant: EVATEC AG, Trübbach (CH)

(72) Inventors: Martin Bless, Malans SG (CH); Thomas Nadig, Heiligkreuz (CH)

(21) Appl. No.: 17/284,047

(22) PCT Filed: Sep. 24, 2019
(86) PCT No.: PCT/EP2019/075657

§ 371 Date: Apr. 9, 2021

(30) Foreign Application Priority Data
Oct. 10, 2018 (CH) 1237/18
Oct. 16, 2018 (EP) PCT/EP2018/078154

(51) Int. Cl. C23C 14/50; C23C 14/35

(52) U.S. Cl. CPC C23C 14/505; C23C 14/541; C23C 14/35

(57) ABSTRACT

For vacuum treatment, a substrate is transported to the inner space of a hollow, cylindric body and is deposited on a holding plate and lifted towards and on a substrate support. The opening of the substrate support is aligned with an opening in the wall of the hollow cylindric body. Substrate plate, substrate support and opening are brought in aligned position with a treatment station, by rotating the hollow cylindric body around its axis, in which position the substrate is vacuum treated.

The present invention is directed on a vacuum treatment apparatus in which a multitude of substrate holder arrangements are arranged along at least one circle locus on a surface locus of a conical, including a cylindrical, body of revolution locus in a vacuum enclosure. At least one vacuum treatment station for treating the substrates is provided at the vacuum enclosure and the substrate holder arrangements pass the treatment station by being rotated relative to the treatment station around the axis of the circle locus of the conical, including cylindrical, body of revolution locus. The substrates are positioned on the substrate holder arrangements so that at least one extended surface of the e.g. plate-shaped substrates extends along or parallel to a tangential plane on the surface locus.

In cases where the substrates have no plane extended surfaces, are in fact bent, the addressed “one extended surface” is to be understood as the plane along which the respective substrate extends.

According to e.g. the EP 1 717 338 the substrates are loaded on and unloaded from the substrate holder arrangements by a substrate handler in a substrate handling chamber. The handler is adapted to transfer the substrates with their extended surfaces along a first plane which is parallel to a tangential plane on a cylinder, outside the cylinder body, and from and on a position in the substrate handling chamber, whereat the substrates extend with their extended surfaces along a second plane which is parallel to a tangential plane on the cylinder.

It is an object of the present invention to provide an alternative vacuum treatment apparatus.

This is achieved by a vacuum treatment apparatus comprising:
a controlled substrate handler;
a substrate vacuum treatment chamber comprising a multitude of substrate holder arrangements arranged along at least one circle locus on a surface locus of a cone body of revolution locus with a cone axis and with a cone-angle α for which there is valid:

0°≤α≤60° and

adapted to respectively hold a substrate with a central normal on at least one extended substrate surface perpendicular to the surface locus and further comprising at least one vacuum treatment station distant from the surface locus and aligned with the at least one circle locus, the at least one circle locus being a circle on the surface locus in a first plane perpendicular to the cone-axis.

The multitude of substrate holder arrangements commonly and the at least one vacuum treatment station are drivingly rotatable relative to each other around the cone-axis.

The substrate handler is adapted to transfer a substrate with its extended surface parallel to a tangential plane of the surface locus towards or from one of substrate holder arrangements and, respectively, from or towards a second plane which second plane is parallel or intersects the tangential plane.

At least some of the substrate holder arrangements comprises a substrate support and a holding plate which is drivingly movable towards and from the substrate support, in a first position more remote from the substrate support and leaving space to slide therebetween a substrate by the substrate handler in alignment with the substrate support and in a second position, closer to the substrate support, securing the substrate in the substrate holder arrangement.

Compared to state of the art apparatuses such an inventive vacuum treatment apparatus has the benefit that most or even all moving parts, e.g. at the substrate holder arrangement and/or at a substrate handler can be arranged or moved in an area apart from the operating area of vacuum treatment station, which effectively lowers the service intervals for components installed within an inventive vacuum treatment chamber. Such treatment stations may comprise PVD-, e.g. sputtering, PECVD-, ALD-, etching or other treatment stations. Further potential cross-contamination from the handler operating for de-/loading operations within the chamber can be minimized.

### Definitions

a) We understand a cylinder as a special case of a cone, namely a cone with a cone-angle of 0°.

b) We understand under the term cone-angle, the angle between the axis of the cone and the surface of the cone body in fact the generatrix-surface.

c) We understand under the term material cone body also called cone jacket, a conical possibly multifaceted body which facets are arranged on a circle, which is a circumference of a cone.

d) We understand in the frame of the present invention, under the term a tangential inner plane of a material hollow cone-body, a plane which is parallel to a tangential plane on the outer surface of the material hollow cone body and extends inside the hollow material cone body. Such tangential inner plane may be located nearby the inner surface of the material hollow cone body e.g. distant therefrom by 0 to 100 mm or by 1 to 80 mm. At least parts of the inner surface of the material cone body may be essentially parallel to the outer surface of the material cone body.

e) We differentiate between a material cone body and a cone body locus. The latter may be defined by the material cone body, which we also call jacket.

When, according to embodiments of the apparatus according to the invention, loading a substrate, e.g. a wafer, on a substrate holder arrangement on a material cone body which is hollow, the substrate may be moved along a tangential inner plane without touching the inner surface of the hollow cone body. Only at a position aligned with a substrate holder arrangement on the material cone body, the substrate is transferred to the substrate holder arrangement by a short radial movement of the substrate handler, e.g. by lowering the substrate handler and depositing the substrate on respective pins of the substrate support or of the holding plate. Thereafter the handler retracts from the treatment chamber and substrates are secured for treatment and rotation of the material cone body or jacket, e.g. clamped or biased into or onto the substrate support in a radial direction, essentially vertical to the surface of the substrate support by the holding plate. The same refers vice-versa to de-loading of the substrates after vacuum treatment(s) in the vacuum treatment chamber.

In one embodiment of the apparatus according to the invention the cone axis is not vertical, is preferably horizontal.

In one embodiment of the apparatus according to the invention the cone axis is vertical.

In one embodiment of the apparatus according to the invention the cone angle is at least approximately 0° and thus the cone-locus is at least approximately a cylinder.

In one embodiment of the apparatus according to the invention the second plane is at least approximately perpendicular to the cone axis.

In one embodiment the second plane is at least approximately parallel to the cone axis.

In one embodiment of the apparatus according to the invention the cone body of revolution locus is defined by a material cone body of revolution also named jacket.

In one embodiment of the apparatus according to the invention the material cone body of revolution is hollow.

In one embodiment of the apparatus according to the invention the substrate handler handles substrates to and from the substrate support arrangements through the inner space of said hollow material cone body of revolution.

In one embodiment of the apparatus according to the invention the substrate handler communicates for substrate transfer via a valve with the vacuum treatment chamber.

In one embodiment of the apparatus according to the invention the substrate handler communicates for substrate transfer via a load-lock with said vacuum treatment chamber. Thus, the substrate handler may reside in an atmosphere with a pressure different from the pressure applied in the vacuum treatment chamber, may even reside in ambient.

In one embodiment of the apparatus according to the invention the substrate handler resides in ambient atmosphere or in a vacuum atmosphere.

In one embodiment of the apparatus according to the invention the substrate handler resides in a chamber.

In one embodiment of the apparatus according to the invention the substrate handler resides in a specific substrate handling chamber or in the addressed substrate vacuum treatment chamber.

In one embodiment of the apparatus according to the invention the substrate handler communicates for substrate transfer via a slit with the vacuum treatment chamber. Thus, this communication may be realized via a slit valve.

One embodiment of the apparatus according to the invention comprises at least one substrate accommodation chamber served for substrate transfer by the substrate handler.

In one embodiment of the apparatus according to the invention the controlled substrate handler is further adapted to handle substrates between the at least one substrate accommodation chamber and the vacuum treatment chamber along the addressed second plane.

In one embodiment of the apparatus according to the invention the controlled substrate handler is further adapted to handle substrates, between the vacuum treatment chamber and the at least one substrate accommodation chamber along the addressed second plane.

In one embodiment of the apparatus according to the invention the substrate handler communicates for substrate transfer via a valve with the at least one substrate accommodation chamber.

In one embodiment of the apparatus according to the invention the substrate handler communicates for substrate transfer via a load-lock with said at least one substrate accommodation chamber.

In one embodiment of the apparatus according to the invention the substrate handler communicates for substrate transfer via a slit with the at least one substrate accommodation chamber. Thus, this communication may be realized via a slit valve.

In one embodiment of the apparatus according to the invention the at least one substrate accommodation chamber is a load-lock chamber.

In one embodiment of the apparatus according to the invention the vacuum treatment chamber comprises more than one of the vacuum treatment stations.

In one embodiment of the apparatus according to the invention the at least one vacuum treatment station is stationary.

In one embodiment the holding plate or at least one of more than one holding plates is radially more remote from the cone-axis than the substrate support.

In one embodiment holding plate or at least one of more than one holding plates is radially less remote from the cone-axis than the substrate support.

In one embodiment the holding plate is frame shaped.

In one embodiment the vacuum treatment chamber does not comprise an etching station, the substrate handler communicating for substrate transfer with an etching station.

In one embodiment the vacuum treatment chamber does not comprise an etching station and at least one of said at least one substrate accommodation chambers is an etching station.

In one embodiment the substrate handler resides in a substrate handling chamber comprising a pumping port.

One embodiment comprises a buffer chamber served for substrate transfer by said substrate handler.

One embodiment comprises a buffer chamber served for substrate transfer by the substrate handler, the buffer chamber being one of the at least one substrate accommodation chambers.

In one embodiment at least one of the substrates supports and of the holding plate comprises an opening freeing a substrate in a substrate holder arrangement for treatment by one of the treatment stations.

In one embodiment at least one of the substrate support and of the holding plate comprises an opening aligned with a substrate position on the substrate holder arrangement which opening is positioned radially inwards from the substrate position, whereby a vacuum treatment station is mounted in an axial position along the axis.

In one embodiment, especially of the just addressed embodiment, the vacuum treatment chamber comprises a cylindrical magnetron.

In one embodiment of the apparatus according to the present invention the cone body of revolution locus is defined by the outer surface of a material cylinder body which is hollow, the inner space of the material cylinder being accessible in direction of the axis, the substrate handler being adapted to transfer a substrate in direction of the axis into and out of the inner space, the substrate support being provided along the rim of an opening in the wall of the hollow material cylinder body, the holding plate being aligned with this opening and in the inner space and movable in radial direction towards and from the substrate support.

Two or more embodiments or features of the apparatus according to the invention may be combined unless being in contradiction.

The invention is further directed to a method of vacuum treating substrates or of manufacturing vacuum treated substrates by means of a vacuum treatment apparatus according to the invention or according to one or more than one of its embodiments.

The present invention is further directed on a method of vacuum treating substrates or of manufacturing vacuum treated substrates, which possibly may be performed by means of a vacuum treatment apparatus according to the invention or according to one or more than one of its embodiments and comprising:
Transporting a substrate into the hollow inner space of a rotatable hollow cylinder in an evacuated chamber;
Biasing the periphery of the substrate towards the rim of an opening in the wall of the rotatable hollow cylinder;
Treating the substrate through the opening;
Releasing the biasing and transporting the treated substrate from the inner space.

The invention will now be further exemplified with the help of figures.

The figures show:

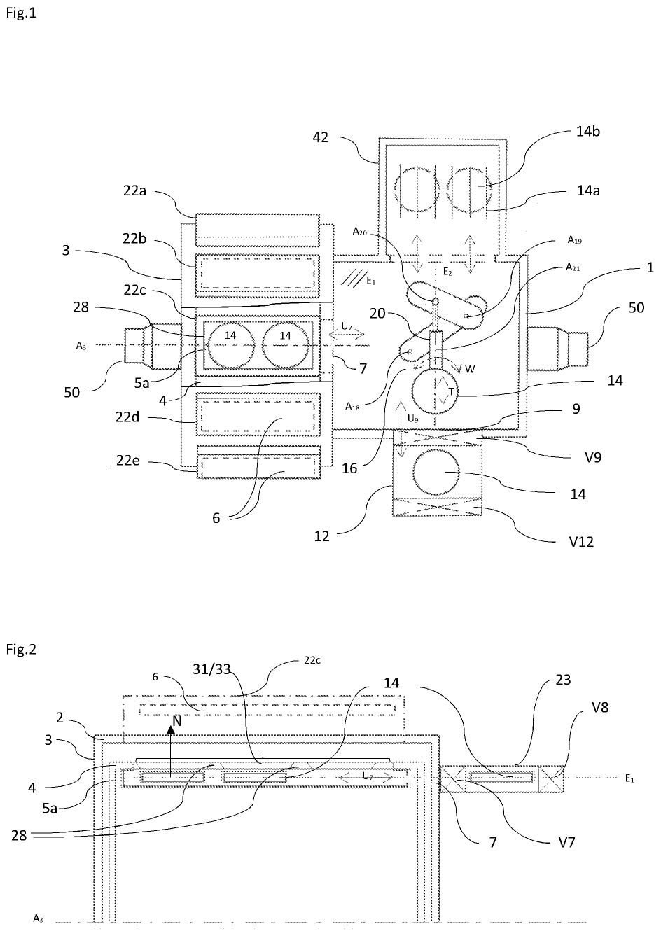

FIG. 1: schematically and simplified a top view of an embodiment of the vacuum treatment apparatus according to the invention;

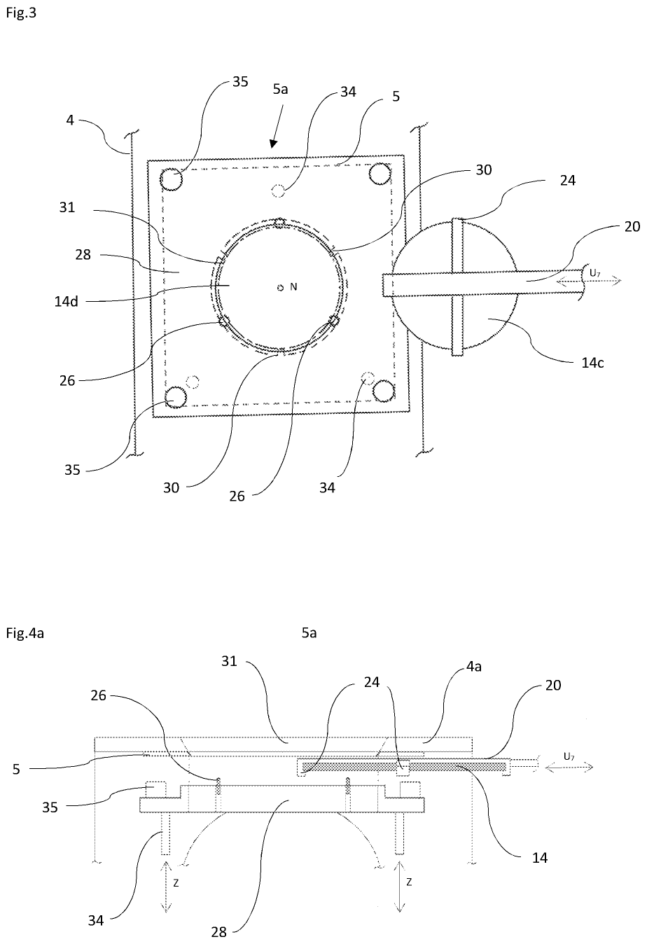

FIG. 2: schematically and simplified in vertical section, an embodiment of a substrate holder arrangement of the vacuum treatment apparatus according to the invention;

FIG. 3: schematically and simplified a top view of a substrate holder arrangement of the vacuum treatment apparatus according to the invention

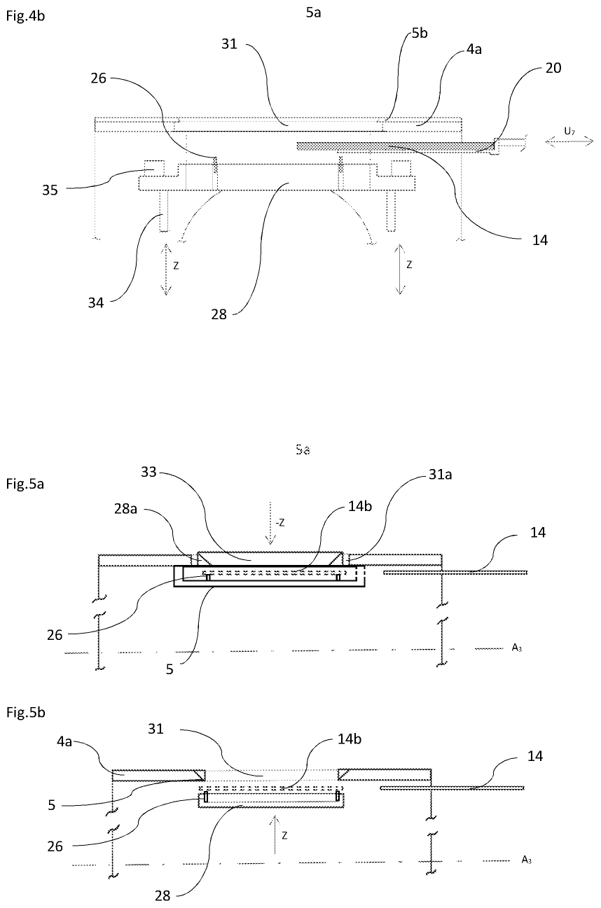

FIGS. 4a and 4b schematically and simplified cross sectional representations of substrate holder arrangements of the vacuum treatment apparatus according to the invention.

FIGS. 5a and b: schematically and simplified cross sectional representations of substrate holder arrangements of the vacuum treatment apparatus according to the invention.

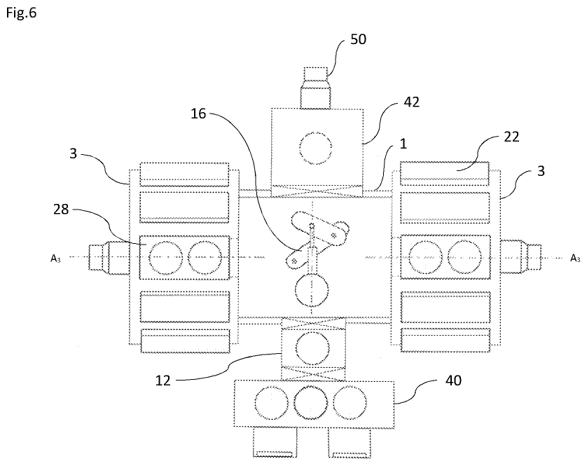

FIG. 6: schematically and simplified, an embodiment of the vacuum treatment apparatus according to the invention;

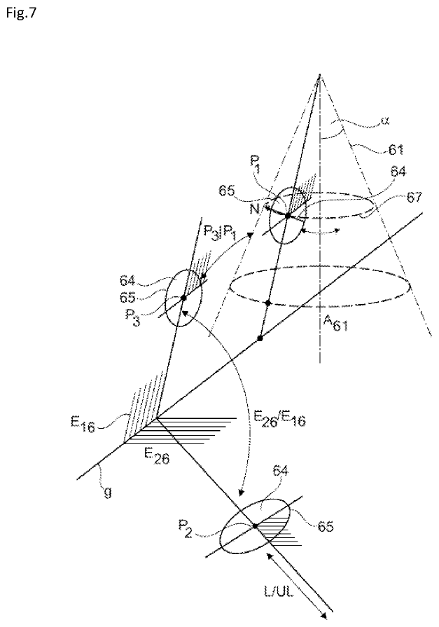

FIG. 7: schematically and simplified the generic substrate handling mechanism at an embodiment of the vacuum treatment apparatus according to the invention.

FIG. 1 shows, in a top view, simplified and schematically, an embodiment of a vacuum treatment apparatus according to the invention. The apparatus comprises a substrate handling chamber 1 and a substrate vacuum treatment chamber 3. The substrate vacuum treatment chamber 3 comprises a multitude of substrate holder arrangements 5a, which are arranged along an inner tangential surface of a cylinder jacket 4—i.e. of a material cone-body of revolution with a cone angle of at least approximately 0°, and with a horizontal axis A₃. The material cone body defines by its outer surface a surface locus. Substrates on the substrate holder arrangements 5a are arranged and held with their central normals N in radial direction with respect to the addressed horizontal axis A₃ as shown in FIG. 2 by the arrow N. The substrate handling chamber 1 communicates via a horizontal substrate handling slit 7, in a horizontal plane E1 that is in the plane of FIG. 1, with the vacuum treatment chamber 3 and by a respectively horizontal substrate handling slit 9, that is again in the plane of FIG. 1 or alternatively in a vertical plane E₂, e.g. in parallel to dash and dot lined axis A₂₁, with a substrate accommodation chamber 12 for accommodating at least one substrate 14 in horizontal position, that is parallel to or in the plane E1 or alternatively parallel to or in plane E2 in the chamber 12.

The horizontal plane E1 is parallel to an inner tangential plane as defined by the hollow material cylinder jacket 4 around horizontal axis A3.

In the substrate handling chamber 1 there is provided a controllably driven substrate handler 16. By means of the substrate handler 16 a substrate 14 is handled in a position which may e.g. be horizontal-in or parallel to plane E1− or vertical-in or parallel to plane E2− between the substrate accommodation chamber 12 and the substrate handling chamber 1, via the respectively oriented slit 9. According to FIG. 1 this substrate transfer is realized in or parallel to the horizontal plane E1.

Further, and according to the embodiment of FIG. 1, the substrate handler 16 is adapted to transfer a substrate 14 insider the jacket 4 in horizontal position between a substrate holder arrangement 5a and the substrate handling chamber 1 via the slit 7 and thus along horizontal plane E1. To do so, the handler 16 has multiple parts 18,19,20 which are swivel-mounted about vertical axes A₁₈, A₁₀, A₂₀. In an embodiment with horizontal transfer of the substrate 14 between the substrate handling chamber 1 and a substrate holder arrangement 5a and with not horizontal substrate transfer between substrate handling chamber 1 and accommodation chamber 12 parts of the handler 16 are additionally drivingly swivelable around axis A21. The part 20, which comprises (not shown in FIG. 1) a substrate gripper for a substrate 14 is on one hand controllably extendable -T- and retractable in the direction of the axis A₂₁ and can be additionally swivel-mounted -W- around axis A₂₁. By the swiveling movement W, e.g. of 90°, the horizontally positioned wafer 14 can be brought e.g. in vertical position and inversely.

The slit 9 may be equipped with a vacuum slit valve as shown in dash-lines by V₉ in FIG. 1. In this case, the substrate accommodation chamber 12 for accommodating at least one substrate 14, may be a bidirectional load lock chamber with a second vacuum slit valve as shown by V₁₂ in dash-line. Alternatively, two unidirectional load lock chambers may be provided for faster input/output of the substrates to and from the substrate handling chamber 1.

The vacuum treatment chamber 3 comprises more than one vacuum treatment stations as shown in FIG. 1 by 22a, 22b, 22c, 22d, 22e, which may e.g. be PVD-, CVD-, PECVD-, ALD-etc. layer deposition stations, etching stations, heating stations, degasser stations etc. The vacuum treatment stations 22ₓ are arranged along a circle around the horizontal axis A₃ radially distant from the substrate holder arrangements 5a and aligned with at least a part of the substrate holder arrangements 5a in the direction of the horizontal axis A₃. The substrate holder arrangements 5a and the more than one vacuum treatment stations 22ₓ are rotatable relative to each other around horizontal axis A₃. Thereby the substrate holder arrangements 5a are sequentially moved in alignment with a respective one of the vacuum treatment stations 22ₓ. In one embodiment, the more than one vacuum treatment station 22x are stationary, whereas the substrate holder arrangements 5a are commonly rotated around horizontal axis A3 by means of a controlled drive (not shown). Substrates are centered with opening 31 or 33 (see FIGS. 2 to 5) to have their surfaces to be treated freely exposed radially outwards towards the stations 22ₓ.

The slit 7 has a width which allows a substrate 14 swiveled or tilted into horizontal position to be passed all-together with the gripping portion of the controlled substrate handler 16 into alignment with a respective one of the substrate holder arrangements 5a. This is schematically shown in FIG. 1 by the double arrow U₇. Please note that through slit 7 as well as through slit 9, U₉, bi-directionally, substrates 14, which have yet not been treated in the substrate vacuum treatment chamber 3 are loaded into this chamber 3 and substrates 14, which have been treated in the addressed chamber 3 are unloaded from the respective substrate holder arrangements 5a towards the chamber 12. Please note, that, in this embodiment:
a) the substrate vacuum treatment chamber 3 comprises a multitude of substrate holder arrangements 5a, arranged along at least one circle locus on a surface locus of a cylinder, i.e. of a cone with a cone axis and with a cone-angle α for which there is valid:

α=0°;
Such surface—and circle—loci are thereby defined by a material, cylindric body, a cylindric jacket which is hollow.
b) The substrate holder arrangements 5a are adapted to hold substrates 14 with central normals N on the extended substrate surfaces perpendicular to the surface locus;
c) The vacuum treatment chamber 3 comprises at least one vacuum treatment station 22ₓ, distant from the surface locus of the cone and aligned with the at least one circle locus, whereby the at least one circle locus is a circle on the surface locus in a plane perpendicular to the cone-axis A₃; whereby the vacuum treatment station 22ₓ is brought into alignment with a radially outer extended surface of a substrate mounted on a respective substrate holder arrangements 5a on the cylinder jacket 31, i.e. the material cone body with 0° cone angle.
d) The multitude of substrate holder arrangements 5a commonly and the at least one treatment station 22ₓ are drivingly rotatable relative to each other around the cone-axis A₃;
e) The substrate handling chamber 1 communicates for substrate transfer with the vacuum treatment chamber 3;
f) In the substrate handling chamber 1, the controlled substrate handler 16 is provided and is adapted and accordingly constructed to transfer a substrate 14 with its extended surface along an inner tangential plane which is parallel to a tangential plane E₁ of the surface locus on or from one of the substrate holder arrangements 5a and from or on a position of the extended surfaces along a second plane E₂ in the substrate handling chamber 1 which second plane E₂ is parallel to or alternatively intersects the tangential plane E₁.

It has to be noted, that the axis A3 may be spatially oriented in any specifically desired direction, e.g. vertically. Thereby the apparatus as described to now i.e. with horizontal axis A3 and as will be further described remains substantially unchanged, except for spatial orientations.

Back to the embodiment of FIG. 1: One further treatment station 42 is shown in FIG. 1 which can be used e.g. for heating, etching, degassing, or any other type of surface treatment or just for storing or buffering a certain number of substrates. Depending on the type of treatment performed in chamber 42, e.g. simultaneously to treatments in chamber 3, substrates 14b (dashed lines) may be oriented in chamber 42 horizontally, warped or vertically as shown by substrates 14a. i.e. in a horizontal plane or in a vertical plane. The latter is e.g. suited for treating a higher number of substrates 14 simultaneously, without the risk to have any particles depositing on the substrates.

In other embodiments the following may be realized:

The substrate handler 16 is installed in an atmosphere having a pressure which is different from the pressure of the atmosphere in the vacuum treatment chamber 3. The atmosphere wherein the substrate handler 16 is installed may be ambient atmosphere. In this case, as schematically and simplified shown in FIG. 2, a load lock 23 with slit valves V₇ and V₈ is provided at or integrated in the location of slit 7 in FIG. 1. The substrate handler 16 is thereby not necessarily installed in a specific handling chamber 1 as of FIG. 1, in fact the substrate handler 16 may be installed not in a chamber at all.

Multiple treatment stations 22 may be provided at the outer circumference 2 of the drum like vacuum treatment chamber 3 e.g. for multilayer coatings using magnetron sputter targets 6—dotted lines—of different materials. It should be mentioned that with the embodiment of FIG. 2, a substrate holder arrangement 5a capable of taking up three substrates is shown, whereas only two substrates 14 are held by the substrate holder arrangement 5a of FIG. 1. In detail, such multi-substrate holder arrangements can be designed similar to a single substrate holder arrangement as discussed exemplarily with the help of FIGS. 3, 4 and 5a, 5b. Thereby one holding mechanism, comprising e.g. holding plates and support pins, may operate on all substrates 14 simultaneously or a separate holding mechanism may be provided for each substrate 14 separately.

FIG. 3 shows schematically and simplified the substrate holder arrangement 5a comprising a holding plate 28 and a substrate support 5—dashed square—in two situations, which clearly do not simultaneously occur, namely with a substrate 14 in a position 14c being fed towards or removed from the substrate holder arrangement 5a and in a position 14d in which a substrate 14 is located and held between the holding plate 28 and the substrate support 5. When a substrate 14 e.g. of circular shape is to be loaded on or removed from the substrate holder arrangement 5a, it is gripped by the gripping part of part 20 (see FIG. 1) of the controlled substrate handler 16. The gripping part 20 may, as schematically shown, comprise controllably releasable hooks 24 which grip a substrate when removing from the chamber 12. When the substrate 14 is conveyed in a position 14d i.e. aligned with a respective holding plate 28, it is released by the gripping e.g. by the hooks 24 and is deposited on studs or pins 26. Thereby, the substrate in position 14d and the gripping parts 20 of the controlled substrate handler 16 are moved beneath the wall 4a of the hollow cylinder drum, i.e. between the wall 4a acting as the substrate support 5 and the radially more inner holding plate 28, as schematically shown in FIG. 4a.

Once the substrate 14, according to position 14d, is deposited on the pins 26, the holding plate 28 is drivingly moved, as shown in FIGS. 4a and b by arrows Z, towards the substrate support 5 and thereby secures the substrate 14 in fixed position 14d to the substrate support 5. This is accomplished, e.g. in that the rim of an opening 31 in the substrate support 5 i.e. in the wall 4a of the cone body, which in this embodiment is cylindric and through which opening 31 the substrate is treated, locally or completely overlaps the periphery of the substrate 14.

Overlapping of the periphery of the substrate 14 when coming to rest at the opening 31 and by the rim of the opening 31 may be realized by a separate support member 5b mounted to the wall 4a as shown in FIG. 4b or directly by the rim of the opening in the wall 4a as shown in FIG. 4a. Thereby the periphery of the substrate may rest all along its extent on the rim of the opening 31 or the rim of opening 31 may comprise radially projecting members as shown in FIG. 3 at 30 and the periphery of the substrate 14 comes to rest only on these projecting members 30.

FIG. 5a shows an embodiment of a substrate holder arrangement 5a which is different from the substrate holder arrangements 5a shown in FIGS. 4a,4b and 5b. Whereas according to the embodiments of FIGS. 4a,4b,5b the periphery of the substrate 14 comes to rest, with respect to axis A3, radially outwards on the substrate support 5 and is brought to that rest position by action of the holding plate 28 moved radially outwards Z towards the substrate support 5, in the embodiment of FIG. 5a the substrate 14 is brought to rest on a substrate support 5 radially inwards and is held in that rest position by moving a holding plate 28a radially inwards −Z through an opening 31a in the wall 4a. As in this case the holding plate 28a is located between the surface of the substrate to be treated and the vacuum treatment station 22, the rim of an opening 33 of the holding plate 28a locally or completely overlaps the periphery of the substrate and provides for accessibility of the substrate to vacuum treatment.

Please note that in the embodiments of FIGS. 4a,4b and 5b the holding plate may be realized without a central opening, i.e. the holding frame plate needs not to be a frame.

The diameter of the openings 31 and 33 decreases towards the surface of the substrate, i.e. these openings are sloped towards the substrate surface. The holding plate 28 is supported, e.g. by drive-studs 34 by which the holding plate 28 is moved into the first position, as shown in FIGS. 4a and b, allowing loading or unloading the substrate and in the second position where the holding plate 28 clamps the substrate in position 14d. Movement from one position into the second is shown by double arrows in Z direction. To provide a save and soft securing of the substrate against substrate support 5 a number, e.g. four elastically, e.g. spring-loaded magnets 35 are provided at a surface area out of the substrate radius and between the periphery of the holding plate 28 and the substrate support 5. As a further alternative, magnetic and resilient components can also be arranged in opposite positions, e.g. the magnets at the holding plate 28 and elastic elements at the substrate support 5 or vice-versa. At least one magnetic and at least one elastic element should be arranged at least at one of the holding plate and of the substrate support in pairwise cooperation to achieve a save and soft clamping.

Contrary to FIG. 4a, FIG. 4b shows a substrate holder 5 which is mounted on the outer circumference of the faceted conical jacket wall 4a, which allows to move the substrate closer to vacuum treatment stations 22 and allows to minimize shadowing of the substrates 14 surface by making the substrate holder 5 flat. Such a substrate holder, similar to embodiments shown in FIGS. 4a and 5b allow also to protect moving parts like the holding plate 28 within the jacket and therefor protect it against vacuum treatment, e.g. coating. This helps to minimizes service efforts. With the embodiment as shown in FIG. 4b the substrate support 5 can also be mounted removable like a liner to protect the jacket i.e. the cone body e.g. against deposition during

PVD processes. In FIG. 4b a fork like version of the substrate handler is shown instead of the gripper in FIGS. 3 and 4a. Such fork like grippers can be used for any handling with horizontal transfer of the substrates.

As shown schematically in the FIGS. 5a and 5b in one embodiment according to FIG. 5b the substrate support 5 is located more distant from the axis A₃ than the holding plate 28 and thus the holding plate 28 is moved in substrate biasing second position in a direction away from the axis A₃, see arrow z.

In another embodiment according to FIG. 5a the substrate support 5 is located closer to the axis A₃ than the holding plate 28a and thus latter is moved in substrate-biasing second position in a direction towards the axis A₃, see arrow −z. In this case the holding plate 28a resides within the opening 31a in the wall 4a.

It should be mentioned with an eye on FIG. 5b that this shows a substrate support 5 and a holding plate 28 on a plane facet section of a multifaceted cylinder jacket or material cone body 4, which makes the construction very simple as in this case contacting members provided at the opening 31, or a peripheral area of the opening 31 can be used as substrate support 5, in analogy to FIGS. 3 and 4. This means that the jacket-wall 4a itself is or comprises the substrate support 5 and no separate supports have to be produced and mounted as with non-facetted cone or cylinder surfaces. Depending on the substrate size from 100 to 400 mm diameter 6- to 14-fold facetted jackets or cone bodies, e.g. 8-, 10-, 12-fold facetted ones can be used with a technical reasonable drum- or jacket-diameter of 1000 to 2000 mm diameter.

FIG. 6 shows simplified and schematically and in analogy to FIG. 1, an embodiment of the vacuum treatment apparatus according to the invention. Thereby, the substrate accommodation chamber 12 for accommodating at least one substrate is a bi-directional load-lock chamber and communicates with an input/output magazine arrangement 40. In this embodiment the substrate handling chamber 1 communicates by further substrate handling slits, possibly with respective slit valves or load locks, directly with additional treatment station(s) 42. In one embodiment, at least one of the treatment stations 42 is an etching station. Thereby, no etching station is provided at the substrate vacuum treatment chamber 3 so that the etching may not influence substrate processing within the substrate vacuum treatment chamber 3. Further, at least one of the treatment stations 42 may be a buffer chamber for buffering one or more than one substrate before or after having been treated. As a further difference to the embodiment of FIG. 1, two or even more substrate vacuum treatment chambers 3, as were described, may be served by the controlled handler 16 in a manner as was described above. In FIG. 6 such a further substrate treatment chamber is addressed with the same reference number 3.

The substrate handling chamber may be constructed so that more than 3 or 4 chambers or stations may be mounted thereto and, through respective slits, possibly with vacuum slit valves or through load locks, be served. Therefor circular, elliptical or polygonal, e.g. pentagonal, hexagonal, octagonal, designs of the handling chamber 1 may be used.

Such an enlarged substrate handling chamber may serve bidirectionally a load-lock chamber, a degasser chamber, a further substrate vacuum treatment chamber 3, as was described, an etching station and a second substrate vacuum treatment chamber 3 as described. This is to show the flexibility of using the vacuum treatment apparatus according to the invention in multiple different configurations.

The passages for the substrate handler towards the vacuum treatment chambers 3 and/or towards further treatment stations 42 may be equipped without a respective valve, or with a respective vacuum valve, or with a respective load lock.

The substrate handling chamber 1 may be in one embodiment separately pumped as shown in FIG. 1 and is then provided with a pumping port with a vacuum pump 50.

FIG. 7 shows the generalized handling concept according to the apparatus of the invention based on the surface locus 61 being a cone with a cone-angle α for which there is valid:

0°≤α≤60°.

One of the multitudes of substrate holder arrangements 5a (not shown in FIG. 7) holds a substrate e.g. a circular substrate 65 in that position P₁ in which it has just be loaded to the respective substrate holder arrangement 5a, or is just to be unloaded from that substrate holder arrangement 5a. The substrate 65 in position P₁ is positioned practically on the surface locus 61 with the normal N on the extended surface 64 of the substrate 65 perpendicular to the surface locus 61 and thus along a respective tangential plane E₁₆ on the surface locus 61. With respect to the axis A₆₁ of the surface locus 61, the substrate 65 is rotated relative to a treatment station (not shown in FIG. 7) along a circular locus 67 away and toward position P₁.

As addressed, the substrate 65 in position P₁ extends along the tangential plane E₁₆ on the surface locus 61.

A substrate 65 is loaded into or removed by the substrate handler (not shown in FIG. 7) in a position P₂ as schematically shown by the arrows L/UL. In the position P₂ within the substrate handling chamber or a further treatment station, if at all provided, the substrate 65 resides with its extended surface 64 along a plane E₂₆ which is parallel to, in analogy to E1 in FIG. 1, FIG. 2 and FIG. 6 or which intersects the tangential plane E₁₆ as shown by intersection line g and in analogy to E2 in FIG. 1. By the controlled substrate handler (not shown in FIG. 7) a yet untreated substrate 65 in position P₂ is grasped and is conveyed into position P₃ where the extended surface 64 of the substrate 65 extends along or practically on the tangential plane E₁₆, still in the substrate handling chamber, if at all provided. This is schematically shown in FIG. 7 by the double arrow E₂₆/E₁₆.

Subsequently the substrate 65 is moved by the controlled substrate handler (not shown in FIG. 7) into the substrate vacuum treatment chamber (not shown in FIG. 7) with its extended surface 64 along or practically in the tangential plane E₁₆ towards and on the surface of the substrate holder arrangement 5a in position P₁. This is schematically shown in FIG. 7 by the double arrow P₃/P₁. A treated substrate 65 is removed from position P₁ via P₃ to P₂ respectively.

Aspects of the apparatus according to the invention are thus to be considered as follows:

Under one aspect of the apparatus according to the invention the at least one vacuum treatment station is positioned radially outward of the material cone body also named jacket or more generically of a cone body of revolution locus.

Under a one aspect of the apparatus according to the invention the at least one vacuum treatment station is positioned radially inward the material cone body also named jacket or more generically the cone body of revolution locus. Such a configuration can be useful if the vacuum treatment station comprises a cylindrical magnetron station in axial position. Contrary to other embodiments of the invention, openings of the substrate holder arrangement have to be provided in a radially inward direction of the substrate surface to be coated, and openings of the jacket are not mandatory.

Under one aspect of the apparatus according to the invention at least some of the substrate holder arrangements comprise a substrate support and, substantially radially outwards with respect to the cone-axis from the substrate support, a holding plate drivingly movable towards and from the substrate support, in a first position more remote from the substrate support leaving space to slide therebetween a substrate by the substrate handler in alignment with the substrate support and in a second position, closer to the substrate support, clamping a substrate on or towards the substrate support.

Under one aspect of the apparatus according to the invention at least some of the substrate holder arrangements comprise a substrate support and, substantially radially inwards with respect to the cone-axis from the substrate support, a holding plate drivingly movable towards and from the substrate support, in a first position more remote from the substrate support leaving space to slide therebetween a substrate by the substrate handler in alignment with the substrate support and in a second position, closer to the substrate support, clamping a substrate on or towards the substrate support.

Under one aspect, aspect A, of the apparatus according to the invention the substrate handler, possibly residing in a specific substrate handling chamber, communicates for substrate transfer via a horizontal or vertical substrate handling first slit, which is located in a first horizontal or vertical plane, with the vacuum treatment chamber as well as via a horizontal or vertical substrate handling second slit, located in a second horizontal or a vertical plane, with a substrate accommodation chamber for accommodating at least one substrate in horizontal or vertical position.

The first horizontal or vertical plane as addressed is parallel to a tangential plane on the surface locus of a cylinder locus as may be defined by a material cylinder. The controllably driven substrate handler is adapted to transfer a substrate from the first horizontal or vertical position into the second horizontal or vertical position and inversely.

Under one aspect of aspect A, the second slit, i.e. a horizontal or a vertical one, is equipped with a vacuum slit valve. In this case and under a further aspect of the treatment apparatus according to the invention, the substrate accommodation chamber, e.g. for accommodating at least one substrate, is a load-lock chamber.

Under one aspect, e.g. of aspect A, the vacuum treatment chamber comprises more than one vacuum treatment stations. These stations are arranged along circles around and coaxial to the horizontal or vertical cylinder-axis and are, considered in radial direction with respect to the addressed horizontal cylinder-axis, distant from the substrate holder arrangements and, further, considered in axial direction with respect to the addressed horizontal or vertical cylinder-axis, aligned with at least a part of the substrate holder arrangements.

Generically under aspects of the apparatus according to the invention, also under aspect A, the vacuum treatment stations may, as example and most generically, comprise etching chambers, layer deposition chambers being PVD- or CVD- or PECVD- or ALD-deposition chambers as well as degasser or cooling chambers. For PVD processes at least one chamber or station may be equipped with a sputter target, e.g. be a magnetron sputter station, facing the substrate surface. The target surface dimensions, e.g. the target radius or width and length, may be at least 10 or 20% larger than the substrate surface dimension to be coated. For PVD- or CVD- or PECVD- or ALD-deposition at least one chamber may be equipped with an upstream or direct evaporator, which may comprise any type of thermal evaporators.

Under aspects of aspect A, the substrate holder arrangements and the addressed more than one vacuum treatment stations are rotatable with respect to each other around the addressed horizontal or vertical cylinder-axis. Thus, in these cases too, by such relative rotation, substrate holders are passed by treatment stations in an aligned manner.

Thereby and under further aspects of aspect A, the more than one vacuum treatment stations are stationary and thus the multitude of substrate holder arrangements is commonly rotated along the addressed surface locus of the cylinder cone body around the addressed horizontal or vertical cylinder-axis

Also, under aspects of aspect A, each of the substrate holder arrangement comprises a substrate support, on which substrates positioned in the substrate holder arrangements rest. Such substrate support may e.g. comprise distinct support pins. The substrate holder arrangements further comprise, radially outwards or inwards with respect to the cone—or cylinder-axis and with respect to the substrate support, a holding plate, which is drivingly moveable towards and from the substrate support. A first position of the holding plate is more remote from the substrate support and leaves space to slide therebetween a substrate by the substrate handler into alignment with the substrate support. In a second position of the holding plate, which is closer to the substrate support than the first position, the holding plate clamps a respective substrate on or towards the substrate holder.

Also, under aspects of aspect A, the vacuum treatment chamber does not comprise an etching station and the substrate handling chamber communicates for substrate transfer by a further substrate handling slit with an etching station. Thereby, it is avoided that by the etching process, other processes in the substrate vacuum treatment chamber are influenced. For instance, that a metal coating on the substrate support and/or on the holding plate is etched by the etching process and may contaminate the substrates.

Also, under aspects of aspect A the addressed first slit, which is, in aspect A, a horizontal one, is equipped with a vacuum slit valve.

Also, under aspects of aspect A, the addressed further slit to an etching station, is equipped with a vacuum slit valve.

Also, under aspects of aspect A, the substrate handling chamber comprises a pumping port.

Under a still further aspect also of aspect A the first slit, which under aspect A is a horizontal one, is positioned distant from the second slit, e.g. a horizontal slit in aspect A, considered in an azimuthal direction with respect to the addressed axis.

Especially under the aspects including aspect A, the substrate handler comprises a first part, which is controllably and drivingly swivel-mounted around a first axis, which is normal, to the addressed horizontal or vertical cone- or cylinder-axis, e.g. vertical, and comprises a second part, which comprises a substrate gripper and which is mounted on the first part. The second part is controllably and drivingly swivelable around a second axis, which is, especially under aspect A, horizontal.

Also, under aspects of aspect A there is provided a buffer chamber, communicating by a still further substrate handling slit with the substrate handling chamber.

Generically in a buffer chamber in substrate transfer communication with the substrate handling chamber, substrates may be buffered in a wait-position before being handed over to the vacuum treatment chamber or to one or more than one vacuum treatment stations directly communicating with the substrate handling chamber.

It must be pointed out that, generically, it is possible to provide at a substrate handling chamber wherein the substrate handler serves more than one substrate vacuum treatment chambers. This also under aspects of aspect A. Such more than one substrate vacuum treatment chambers may be served by substrates from the substrate handling chamber.

Under another aspect of the vacuum treatment apparatus at least one of the substrate support and of the holding plate comprises openings aligned with a substrate position and positioned radially inwardly with respect to the substrate position, whereby a vacuum treatment station is mounted in an axial position along the cone axis A3, A61.

Thereby the vacuum treatment station may comprise a cylindrical magnetron especially as the addressed vacuum treatment station along the cone axis.

What is claimed is:

1. A vacuum treatment apparatus comprising:
a controlled substrate handler (16);
a substrate vacuum treatment chamber (3) comprising a multitude of substrate holder arrangements (5a) arranged along at least one circle locus (67) on a surface locus (61) of a cone body of revolution locus with a cone axis (A3) and with a cone-angle α for which there is valid:
0°≤α≤60°
and adapted to respectively hold a substrate (14, 65) with a central normal (N) on at least one extended substrate surface (64) perpendicular to said surface locus (61) and further comprising at least one vacuum treatment station (22), distant from said surface locus and aligned with said at least one circle locus (67), said at least one circle locus (67) being a circle along said surface locus in a first plane perpendicular to said cone-axis (A₃, A₆₁);
said multitude of substrate holder arrangements (5a) commonly and said at least one vacuum treatment station (22) being drivingly rotatable relative to each other around said cone-axis (A₃, A₆₁);
said substrate handler (3) being adapted to transfer a substrate (14, 65) with its extended surface (64) parallel to a tangential plane (E₁₆) of said surface locus (61) towards or from one of said substrate holder arrangements (5a) and, respectively, from or towards a second plane (E₂₆), which second plane is parallel or intersects said tangential plane (E₁₆);
wherein at least some of said substrate holder arrangements (5a) comprises a substrate support (5) and a holding plate (28) which is drivingly movable towards and from said substrate support (5), in a first position more remote from said substrate support (5) and leaving space to slide a substrate therebetween by said substrate handler in alignment with said substrate support (5) and in a second position, closer to said substrate support (5), securing the substrate in said substrate holder arrangement (5a).

2. The vacuum treatment apparatus of claim 1 wherein said cone axis is not vertical, is preferably horizontal.

3. The vacuum treatment apparatus of claim 1 wherein said cone axis is vertical.

4. The vacuum treatment apparatus of claim 1 wherein said cone angle is at least approximately 0° said cone being thereby at least approximately a cylinder.

5. The vacuum treatment apparatus of claim 1 wherein said second plane is at least approximately perpendicular to the cone axis.

6. The vacuum treatment apparatus of claim 1 wherein said second plane is at least approximately parallel to the cone axis.

7. The vacuum treatment apparatus of claim 1 wherein said cone body of revolution locus is defined by a material cone body of revolution.

8. The vacuum treatment apparatus of claim 7 wherein said material cone body of revolution is hollow.

9. The vacuum treatment apparatus of claim 8 wherein said substrate handler handles substrates to and from said substrate support arrangements through the inner space of said hollow material cone body of revolution.

10. The vacuum treatment apparatus of claim 1 said substrate handler communicating for substrate transfer via a valve with said vacuum treatment chamber.

11. The vacuum treatment apparatus of claim 1 said substrate handler communicating for substrate transfer via a load-lock with said vacuum treatment chamber.

12. The vacuum treatment apparatus of claim 1 said substrate handler residing in ambient atmosphere or in a vacuum atmosphere.

13. The vacuum treatment apparatus of claim 1 said substrate handler residing in a chamber.

14. The vacuum treatment apparatus of claim 1 said substrate handler residing in a substrate handling chamber or in said substrate vacuum treatment chamber.

15. The vacuum treatment apparatus of claim 1 said substrate handler communicating for substrate transfer via a slit with said vacuum treatment chamber.

16. The vacuum treatment apparatus of claim 1 comprising at least one substrate accommodation chamber served for substrate transfer by said substrate handler.

17. The apparatus of claim 16 said substrate handler being further adapted to handle substrates between said at least one substrate accommodation chamber and said vacuum treatment chamber along said second plane.

18. The apparatus of claim 16 said substrate handler being further adapted to handle substrates between said vacuum treatment chamber and said substrate accommodation chamber along said second plane.

19. The vacuum treatment apparatus of claim 16 said substrate handler communicating for substrate transfer via a valve with said at least one substrate accommodation chamber.

20. The vacuum treatment apparatus of claim 16 said substrate handler communicating for substrate transfer via a load-lock with said at least one substrate accommodation chamber.

21. The vacuum treatment apparatus of claim 16 said substrate handler communicating for substrate transfer via a slit with said at least one substrate accommodation chamber.

22. The vacuum treatment apparatus of claim 16, wherein said at least one substrate accommodation chamber is a load-lock chamber.

23. The vacuum treatment apparatus of claim 1, wherein said vacuum treatment chamber comprises more than one vacuum treatment stations.

24. The vacuum treatment apparatus of claim 1, wherein said at least one vacuum treatment station is stationary.

25. The vacuum treatment apparatus of claim 1, wherein said holding plate or at least one of more than one holding plates is more remote from said cone-axis than said substrate support.

26. The vacuum treatment apparatus of claim 1, wherein said holding plate or at least one of more than one holding plates is less remote from said cone-axis than said substrate support.

27. The vacuum treatment apparatus of claim 1 wherein said holding plate is frame shaped.

28. The vacuum treatment apparatus of claim 1, wherein said vacuum treatment chamber does not comprise an etching station, said substrate handler communicating for substrate transfer with an etching station.

29. The vacuum treatment apparatus of claim 16 wherein said vacuum treatment chamber does not comprise an etching station and at least one of said at least one substrate accommodation chambers is an etching station.

30. The vacuum treatment apparatus of claim 1, wherein said substrate handler resides in a substrate handling chamber comprising a pumping port.

31. The vacuum treatment apparatus of claim 1 comprising a buffer chamber served for substrate transfer by said substrate handler.

32. The vacuum treatment apparatus of claim 16 comprising a buffer chamber served for substrate transfer by said substrate handler, said buffer chamber being one of said at least one substrate accommodation chambers.

33. The vacuum treatment apparatus of claim 1 whereby at least one of the substrate support (5) and of the holding plate (28) comprises an opening (31, 33) freeing a substrate in a substrate holder arrangement (5a) to treatment by one of said treatment stations (22).

34. The vacuum treatment apparatus of claim 1 whereby at least one of the substrate support (5) and of the holding plate (28), comprises an opening aligned with a substrate position (14b) on a substrate holder arrangement (5a) which are positioned radially inwards from said substrate position, whereby a vacuum treatment station is mounted in an axial position along the axis (A3, A61).

35. The vacuum treatment apparatus of claim 1, whereby the vacuum treatment chamber comprises a cylindrical magnetron.

36. The vacuum treatment apparatus of claim 1 wherein said cone body of revolution locus is defined by the outer surface of a material cylinder body which is hollow, the inner space of said material cylinder being accessible in direction of said axis, said substrate handler being adapted to transfer a substrate in direction of said axis into and out of said inner space, said substrate support being provided along the rim of an opening in the wall of said hollow material cylinder body, said holding plate being aligned with said opening and in said inner space and movable in radial direction towards and from said substrate support.

37. A method of vacuum treating substrates or of manufacturing vacuum treated substrates by making use of a vacuum treatment apparatus according to claim 1.

38. A method of vacuum treating substrates or of manufacturing vacuum treated substrates, comprising:
Transporting a substrate into a hollow inner space of a rotatable hollow cylinder in an evacuated chamber;
Biasing a periphery of said substrate towards a rim of an opening in a wall of said rotatable hollow cylinder;
Treating said substrate through said opening;
Releasing said biasing and transporting said treated substrate from said inner space.
